(19) United States
(12) Patent Application Publication
(10) Pub. No.: US 2007/0223192 A1
(43) Pub. Date: Sep. 27, 2007

(54) Transport system

(75) Inventor: Brian A. Hamman, Krugerville, TX (US)

Correspondence Address: Arthur W. Fisher;Patent Dominion Partnership, LP, 6103 Twin Oaks Circle, Dallas, TX, 75240, US

(73) Assignee: QNX Cooling Systems Inc.

(21) Appl. No.: 11/388,047

(22) Filed: Mar. 24, 2006

(51) Int. Cl. H05K 7/20

(52) U.S. Cl. 361/688

(57) ABSTRACT

A cooling system with one or more heat transfer units is presented. A number of embodiments are presented. The heat transfer unit engages heat generating components on a circuit board and creates a thermal coupling with the heat generating components when the circuit board is connected to the electronic system. Another embodiment includes a coil of stiff material inserted into the coolant conduits to prevent crimping of the conduits when bent or angled and to prevent undesired suction effects.

### CROSS REFERENCE TO RELATED APPLICATIONS

Reference is made to pending U.S. patent application Ser. No. 10/688,587 filed Oct. 18, 2003 for a detailed description of cooling systems and various heat transfer units and heat exchangers and their operation.

### BACKGROUND OF THE INVENTION

### DESCRIPTION OF THE RELATED ART

At the heart of data processing and telecommunication devices are processors and other heat-generating components which are becoming increasingly more powerful and generating increasing amounts of heat. As a result, more powerful cooling systems are required to prevent these components from thermal overload and resulting system malfunctions or slowdowns.

Traditional cooling approaches such as heat sinks and heat pipes are unable to practically keep up with this growing heat problem. As these components become increasingly more powerful, the size and weight of air-cooled solutions become more problematic as well. In smaller housings or rack mounted systems, the space required for air-cooled solutions becomes unacceptable. Cooling systems which use a liquid or gas to cool these heat generating components are becoming increasingly needed and more viable. These systems utilize heat transfer units thermally coupled to the heat generating components for absorbing or extracting heat from the heat generating components into a coolant flowing there through. The coolant, now heated, is directed to a heat exchanger where heat is dissipated from the coolant, creating cooled coolant and returned to the heat transfer unit to repeat the cycle.

The heat transfer units typically comprise a housing with a cavity there through for the coolant to flow through. The contact surface (with the heat generating components) must have excellent thermal transfer capability and a wide variety of materials can be used such as copper.

For today's more complex systems, including, but not limited to, servers and other rack mounting data processing and telecommunication systems, the system is capable of having a different number of circuit cards with heat generating components such as, but not limited to, microprocessors connected to the system at any one time. Moreover, these circuit cards must be capable of being connected or disconnected at any time and while the server system or main system is running. Most, if not all, of these circuit cards will have one or more heat generating components requiring cooling by a heat transfer unit. Consequently, an easy, cost-efficient and reliable method of coupling the heat transfer units to the heat generating components for cooling is needed.

Thus, there is a need in the art for a method and apparatus for a cost-efficient, seamless and fast method of thermally coupling heat transfer units to heat generating components on line. There is also a need in the art for a cost-effective conduit arrangement which will retain its shape and not deter coolant flow when bent or formed to curve or angle and which will not create undesired suction effects on the coolant transport system.

### SUMMARY OF THE INVENTION

A method and apparatus for a cooling system having a coolant for cooling one or more heat-generating components in an electronic system comprising one or more heat transfer units having the coolant circulating there through for transferring heat from the heat-generating components to the coolant; and wherein the heat transfer units are thermally coupled to the heat-generating components when the heat-generating components are connected to the electronic system.

The method and apparatus as described above further comprising: means for securing the heat transfer units directly or indirectly to the housing of the electronic system.

The method and apparatus as described above wherein one or more heat transfer units are movable such that, when the heat-generating components are connected to the electronic system, the heat transfer units are moved to form the thermal coupling with the heat-generating components when the heat-generating components are connected to the electronic system.

The method and apparatus as described above wherein the movable heat transfer units comprise one or more heat transfer unit housings having a cavity for coolant to circulate there through; one or more means for pivoting or hinging the heat transfer units directly or indirectly to the electronic system housing; and wherein, when the heat-generating components are connected to the electronic system, the means for pivoting or hinging is engaged moving the heat transfer units into thermal coupling with the heat-generating components.

The method and apparatus as described above wherein one or more heat transfer units are stationary.

The method and apparatus as described above wherein one or more heat transfer units have an inlet for receiving cooled coolant and an outlet for directing heated coolant from the heat transfer unit and wherein the inlet is positioned below an outlet for enhancing convective circulation of the coolant.

The method and apparatus as described above wherein one or more heat-generating components are disposed on a circuit board and are thermally coupled to one or more heat transfer units when the circuit board is connected to the electronic system.

The method and apparatus as described above further comprising contact means coupled to one or more heat transfer units for ensuring sufficient thermal coupling of the heat transfer units to the heat-generating components when the heat-generating components are connected to the electronic system.

The method and apparatus as described above further comprising reception means coupled to the circuit board for receiving the contact means and securing the thermal coupling of the heat transfer units to the heat-generating components.

The method and apparatus as described above wherein the contact means and the reception means are disposed such that the circuit board cannot be connected to the electronic system incorrectly.

The method and apparatus as described above further comprising one or more heat exchange units for receiving heated coolant from the heat transfer units, dissipating heat from the coolant thereby creating cooled coolant, and directing the cooled coolant to the heat transfer units; and transport means for transporting the coolant between the heat exchange units and the heat transfer units.

The method and apparatus as described wherein the transport means comprises one or more thin-walled, flexible conduits for transporting the coolant; and support means disposed within the conduits for maintaining a consistent shape of the conduits in the electronic system.

A method and apparatus for a cooling system having a coolant for cooling one or more heat-generating components in an electronic system and having a coolant transport system, the coolant transport system comprising one or more thin-walled, flexible conduits for transporting the coolant; and support means disposed within the conduits for maintaining a consistent shape of the conduits in the electronic system.

The method and apparatus as described above for preventing undesired suction effects in the conduits.

The method and apparatus as described above wherein the support means is a coil of suitably rigid material.

### BRIEF DESCRIPTION OF THE DRAWINGS

FIG. 1A is a partial side view of a circuit board with a heat generating component.

FIG. 1B is a partial side view of a system housing with a backplane and a movable heat transfer unit.

FIG. 1C is a partial side view of the circuit board of FIG. 1A connected to the backplane of FIG. 1B.

FIG. 1D is a partial side view of a circuit board with a heat generating component.

FIG. 1E is a partial side view of a system housing with a backplane and a stationary heat transfer unit.

FIG. 1F is a partial side view of the circuit board of FIG. 1D connected to the backplane of FIG. 1E.

FIG. 2 is a partial front view of circuit board with a heat generating component and the housing and backplane of the system with a movable heat transfer unit. FIG. 2 also contains a schematic of a cooling system with a heat exchanger connected to a movable heat transfer unit.

FIG. 3A is a partial top view of movable heat transfer unit thermally coupled to a heat generating component on a circuit board and a retention mechanism for securing the thermal couple.

FIG. 3B is a partial side view of FIG. 3A.

### DETAILED DESCRIPTION

Whilst the making and using of various embodiments of the present invention are discussed in detail below, it should be appreciated that the present invention provides many applicable inventive concepts, which can be embodied in a wide variety of specific contexts. The specific embodiments discussed herein are merely illustrative of specific ways to make and use the invention and do not limit the scope of the invention.

It should be understood that the principles and applications disclosed herein can be applied in a wide range of data processing systems, telecommunication systems and other systems such as electrical and electronic systems. The present invention is particularly suited, but not limited to, rack mountable systems such as servers.

In the present invention, heat produced by a heat generating component, such as, but not limited to, a microprocessor in a data processing system, is transferred to a coolant in a movable heat transfer unit and dissipated in the cooling system. Liquid cooling solves performance and reliability problems associated with heating of various heat generating components in electronic systems.

The present invention may be utilized in a number of computing, communications, and personal convenience applications. For example, the present invention could be implemented in a variety of servers, workstations, exchanges, networks, controllers, digital switches, routers, personal computers which are portable or stationary, cell phones, and personal digital assistants (PDAs) and many others. As mentioned above, the present invention is particularly suited for rack mountable systems such as a server or the like, and one in which the number of heat-generating components requiring cooling operating may vary at any given time.

The present invention is equally applicable to a number of heat-generating components (e.g., central processing units, optical devices, data storage devices, digital signal processors or any component that generates significant heat in operation) within such systems. Furthermore, the dissipation of heat in this cooling system may be accomplished in any number of ways by a heat exchange unit of various designs, but which are not discussed in detail in this application.

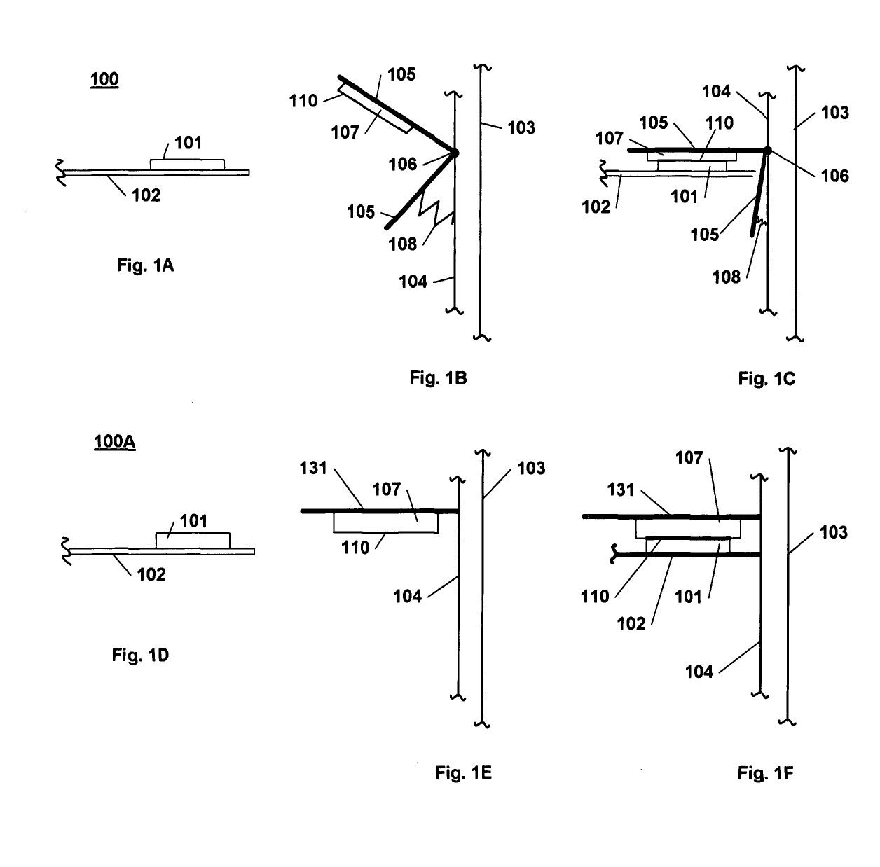

Referring now to FIG. 1A, a partial side view of a circuit board 102 and a heat-generating component 101 such as, but not limited to, a micro-processor, is depicted. The heat generating component 101 is to be cooled by the movable heat transfer unit system 100.

FIG. 1B depicts a partial side view of a movable heat transfer unit system 100. An electronic system housing 103 with a backplane 104 is shown. A bracket 105 is connected to the backplane 104 by a pivot or hinge joint 106. A spring 108 pushes at the lower portion of bracket 105 causing the upper portion of the bracket 105 to be displaced at an angle. A heat transfer unit 107 is affixed to the upper portion of the bracket 105.

In FIG. 1B, the bracket 105 is depicted as a metal, L-shaped bracket. It will be appreciated that bracket 105 may formed in a variety of shapes and from a variety of materials. The material should be rigid or semi-rigid such as many metals or plastics but it should have some flexibility to allow a slight bend when the circuit board 102 fully engages the backplane 104 as described below in connection with FIG. 3C. The dimensions of the bracket 105 are variable depending on the application of the movable heat transfer unit system 100. It will be appreciated that the pivot mechanism may be a various sizes, shapes and dimensions so long as the bracket 105 is movable.

In FIG. 1C, a side view of the circuit board 102 with the heat generating component 101 is shown connected to the electronic system backplane 104 with the movable heat transfer unit 107. As the circuit board 102 is inserted into the backplane 104, the end of the circuit board engages the lower portion of bracket 105 causing the bracket to pivot about the pivot mechanism or joint 106 and bringing heat transfer unit 107 in direct thermal contact with the heat generating component 101. When the circuit board 102 is fully inserted into the back plane 104, spring 108 is fully compressed. If the bracket 105 is semi rigid or has some flexibility, the upper portion of the bracket 105, which would otherwise rotate past horizontal, will bend slightly permitting a tight thermal couple of the heat transfer unit 107 with the heat generating component 101.

When the circuit board 102 is disconnected from the backplane 104, spring 108 forces the bracket 105 to rotate, disengaging the thermal couple between heat transfer unit 107 and heat generating component 101. To ensure a uniform thermal couple between heat transfer unit 107 and heat generating component 101, a thermal paste may be applied to the surface of the heat generating component 101, or surface 110 of the heat transfer unit 107, or both.

Referring now to FIG. 1D, a partial side view of a circuit board 102 and a heat-generating component 101 such as, but not limited to, a microprocessor, is depicted. The heat generating component 101 is to be cooled by the stationary heat transfer unit system 100A.

FIG. 1E depicts a partial side view of a stationary heat transfer unit system 100A. An electronic system housing 103 with a backplane 104 is shown. A bracket 131 or other supporting mechanism is connected to the backplane 104. A heat transfer unit 107 is affixed to the bracket 131.

In FIG. 1E, the bracket 131 is depicted as a metal bracket. It will be appreciated that bracket 131 may formed in a variety of shapes and from a variety of materials. The material should be rigid or semi-rigid such as many metals or plastics but it should have some flexibility to allow a slight bend when the circuit board 102 fully engages the backplane 104 as described below in connection with FIG. 3F. The dimensions of the bracket 131 are variable depending on the application of the stationary heat transfer unit system 100A and it may be affixed to the backplane 104 by a variety of methods as will be obvious to one skilled in the art.

It will be appreciated that all of the embodiments of the present invention encompass the use of various forms or types of heat transfer unit or the combination of different types of heat transfer units. The size and shape of the heat transfer unit 107 will be determined by the physical and thermal characteristics of the heat generating component 101. In FIGS. 1B and 1E, heat transfer unit 107 is depicted as a housing with a flat, thermally-conductive surface 110 for thermally coupling to heat generating component 101. The housing has a cavity to allow coolant to flow through and absorb heat from the heat generating component 101 when the thermal couple between heat transfer unit 107 and heat generating component 101 is established (in FIGS. 1C and 1F).

In FIG. 1F, a side view of the circuit board 102 with the heat generating component 101 is shown connected to the electronic system backplane 104 with the stationary heat transfer unit 107. As the circuit board 102 is inserted into the backplane 104, the heat generating component 101 comes in contact with contact surface 110 of heat transfer unit 107 and starts the formation of a thermal coupling between the heat transfer unit 107 and the heat generating component 101. When the circuit board 102 is fully inserted into the back plane 104, a complete thermal couple between the heat transfer unit 107 and the heat generating component 101 is formed. It is desirable if bracket 131 has some flexibility to allow the heat generating component 101 to force the heat transfer unit 107 upward and thereby form a tight thermal couple.

When the circuit board 102 is disconnected from the backplane 104, The thermal couple between the heat generating component 101 and heat transfer unit 107 is undone. To ensure a uniform thermal couple between heat transfer unit 107 and heat generating component 101, a thermal paste may be applied to the surface of the heat generating component 101, or surface 110 of the heat transfer unit 107, or both.

It will be appreciated that the present invention encompasses a variety of methods of forming the thermal couple between a heat transfer unit and heat generating component, whether the heat transfer unit is movable or stationary and that the descriptions that follow for a movable heat transfer unit apply to a stationary heat transfer unit as well. In all embodiments of the present invention, the thermal coupling between the heat transfer unit and the heat generating component occurs during the process of connecting the heat generating components to the electronic system and regardless of the method of physically connecting the heat transfer unit to the system.

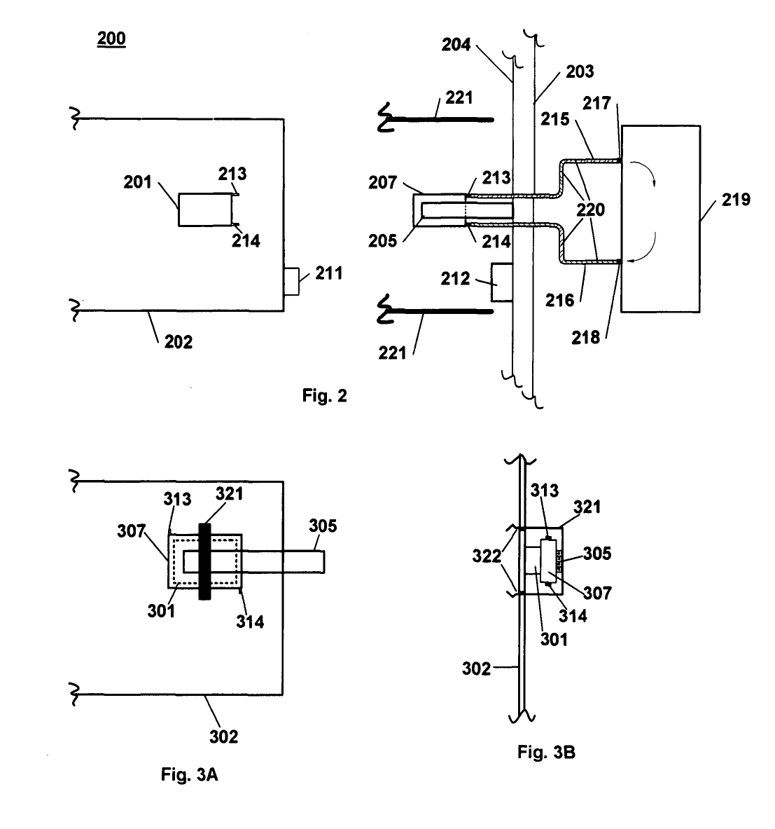

In FIG. 2, a front view of a circuit board 102 with a heat generating component 101 and an electrical connector 211. A partial side view of housing 203 and backplane 204 with the movable heat transfer unit 207 affixed to bracket 205 is also shown. FIG. 2 also includes the remainder of the cooling system 200 including heat exchange unit 219 and conduits 215 and 216.

Circuit board 202 inserted into guide rails 221 for connection to the backplane 204. When inserted, electrical connector 211 connects to receptacle 212 providing the circuit board 202 with electrical power. Additionally, and as described above, heat transfer unit 207 thermally couples to heat generating component 201 (which is now operational and generating heat).

Cooled coolant from heat exchange unit 219 enters the heat transfer unit 207 at inlet 214. As it flows through the heat transfer unit 207, heat is absorbed into the coolant from heat generating component 201, cooling the component 201 and heating the coolant. The heated coolant exits the heat transfer unit 207 at outlet 213 and transported via conduit 215 to the inlet 217 of heat exchange unit 219. The heat exchange unit 219 dissipates heat from the coolant and provides cooled coolant at it outlet 218 which is transported to the inlet 214 of heat transfer unit 207 via conduit 216 and the cycle is repeated again.

It will be further understood that, in all of the embodiments of the present invention, any number and type of heat exchange units may be employed including heat exchange units with or without reservoirs; with or without a pump; and with or without fans or other air flow devices. It should also be appreciated that a remotely mounted or external heat exchange unit may also be used. The heat exchange unit may be used to cool one or more heat transfer units connected in series or parallel or any combination thereof.

Any number of coolants, liquid or gas, may be used with any of embodiments of the present invention such as, for example, a propylene-glycol based coolant. The scope of this invention also includes refrigerated cooling systems of all types including, but not limited to, systems utilizing both conventional Freon based and solid state cooling systems.

Whenever possible, it is desirable to orient the heat transfer units, such as heat transfer units 207, in the system so that cooled coolant is received at a point below where heated coolant exits the heat transfer unit 207. This orientation allows the cooling system to take advantage of convective circulation of the coolant since heated coolant will naturally rise and cooled coolant will naturally drop. In this manner, the convective circulation or flow of the coolant can assist forced circulation, by a pump for example, and provide additional cooling of the heat generating components even after power is shut down to the electronic system through convective circulation. Similarly, and for the same reasons, it is desirable to orient the heat exchange unit, such as heat exchange unit 219, in the system so that heated coolant is received at a point above where cooled coolant exits the heat exchange unit.

It will be appreciated that, in larger systems, and particularly systems such as rack mountable server systems, there will be a plurality of circuit boards, such as circuit board 202, that connect into the system or system backplane 204. In these systems, it is common to have circuit boards being added to the system or removed from the system from time-to-time and done so while the system is on line. Moreover, circuit boards may have more than one heat generating component which can be cooled by one or more movable heat transfer units, such as heat transfer unit 207.

An advantage of the present invention is that, for such larger systems, the entire cooling system, such as cooling system 200, or plurality of cooling systems can be installed, tuned and filled with coolant during the assembly of the system housing and will not need further adjustment irrespective of how many circuit cards and/or heat generating components are connected to the system at any one time. The coolant volume and pressure can be maintained at a constant level at all times and the coolant transport system sealed and unbroken at all times. This will eliminate the need for leak catchers and for coolant regulators to regulate pressure and/or volume.

In FIG. 2, the conduits 215 and 216 are depicted with a support mechanism 220 shown therein. The support mechanism is a coil of stiff material including, but not limited to, such materials as metal or plastic which enable the conduits to be made out of a thin-walled, flexible material for space efficient and cost efficient deployment of the coolant transport system. Thin-walled, flexible materials have a tendency to crimp or collapse when bent significantly. If so, that would severely restrict the flow of coolant through the transport systems. Additionally, very cost-effective, lightweight and flexible materials may have a tendency to collapse under significant suction situations which may be created by a pump in the heat exchange unit. In either case, such effects may have a significant adverse effect on the coolant pressure and flow rates in the cooling system. By disposing a coil or other shape of stiff material, the conduits can be angled as need in the system without crimps or collapses and without creating undesired suction effects. This will enable the conduits to be neatly and space-efficiently disposed in the system, in one or more harnesses or in a stand-alone manner, while maintaining the integrity of the coolant flow. This will also permit the use of very flexible, light weight, inexpensive materials for the conduits.

Referring now to FIG. 3A, a front view of a circuit board 302 is shown with a retention or locking mechanism for the thermal coupling of the movable heat transfer unit 307 to the heat generating component 301. Heat generating component 301 is disposed on circuit board 302. A bracket 305 to which the heat transfer unit 307 is affixed is also depicted for when the circuit board 302 is fully inserted into the backplane (not shown) and a thermal coupling of the movable heat transfer unit 307 to the heat generating component 301 has occurred. Heat transfer unit 307 is depicted with an inlet 314 for receiving cooled coolant and an outlet 313 for heated coolant in FIGS. 3A and 3B. A clip 321 is also depicted as affixed to the bracket 305. The pivot or hinge point for bracket 305 as well as the system housing and backplane are not shown in FIGS. 3A and 3B.

In FIG. 3B, a side-view of the circuit board 302 and movable heat transfer unit 307 of FIG. 3A is depicted. In FIG. 3B, circuit board 302 is shown with a pair of holes 322 there through. As the circuit board 302 is inserted into the system, its movement into bracket 305 causes bracket 305 to pivot as described above and for heat transfer unit 307 to thermally couple to heat generating component 301. Additionally, the ends of retention clip 321 insert through holes 322 and clip 321 to the underside of circuit board 302 when circuit board 302 is fully inserted into the system.

The tension set at the ends of retention clip 321 is such that, when circuit board 302 is fully inserted adequate pressure is applied to the thermal coupling of heat transfer unit 307 to heat generating component 301 but not so great as to prevent easy disconnecting of circuit card 302 from the system when desired. Retention clip may be made from any number of materials including metal. It will be appreciated that a variety of designs for this clip can be used as well.

The retention clip 321 and the circuit card holes 322 may also be used to prevent the insertion of a circuit card into an incorrect position in the system. Specifically, by varying the placement of the retention clip 321 along the bracket 305 and correspondingly, the placement of holes 322 in the circuit board 302 for each different type of circuit board to be connected to the system, only a circuit board designed for a particular slot in the system will be able to lock into place.

Thus, the present invention has been described herein with reference to particular embodiments for particular applications. Those having ordinary skill in the art and access to the present teachings will recognize additional modifications, applications, and embodiments within the scope thereof.

It is, therefore, intended by the appended claims to cover any and all such applications, modifications, and embodiments within the scope of the present invention.

What is claimed is:

1. A cooling system having a coolant for cooling one or more heat-generating components in an electronic system comprising:
one or more heat transfer units having the coolant circulating there through for transferring heat from the heat-generating components to the coolant; and
wherein the heat transfer units are thermally coupled to the heat-generating components when the heat-generating components are connected to the electronic system.

2. The cooling system as set forth in claim 1 further comprising:
means for securing the heat transfer units directly or indirectly to the housing of the electronic system.

3. The cooling system as set forth in claim 2 wherein one or more heat transfer units are movable such that, when the heat-generating components are connected to the electronic system, the heat transfer units are moved to form the thermal coupling with the heat-generating components when the heat-generating components are connected to the electronic system.

4. The cooling system as set forth in claim 3 wherein the movable heat transfer units comprise:
one or more heat transfer unit housings having a cavity for coolant to circulate there through;
one or more means for pivoting or hinging the heat transfer units directly or indirectly to the electronic system housing; and
wherein, when the heat-generating components are connected to the electronic system, the means for pivoting or hinging is engaged moving the heat transfer units into thermal coupling with the heat-generating components.

5. The cooling system as set forth in claim 2 wherein one or more heat transfer units are stationary.

6. The cooling system as set forth in claim 2 wherein one or more heat transfer units have an inlet for receiving cooled coolant and an outlet for directing heated coolant from the heat transfer unit and wherein the inlet is positioned below an outlet for enhancing convective circulation of the coolant.

7. The cooling system as set forth in claim 2 wherein one or more heat-generating components are disposed on a circuit board and are thermally coupled to one or more heat transfer units when the circuit board is connected to the electronic system.

8. The cooling system as set forth in claim 7 further comprising:
contact means coupled to one or more heat transfer units for ensuring sufficient thermal coupling of the heat transfer units to the heat-generating components when the heat-generating components are connected to the electronic system.

9. The cooling system as set forth in claim 8 further comprising:
reception means coupled to the circuit board for receiving the contact means and securing the thermal coupling of the heat transfer units to the heat-generating components.

10. The cooling system as set forth in claim 9 wherein the contact means and the reception means are disposed such that the circuit board cannot be connected to the electronic system incorrectly.

11. The cooling system as set forth in claim 2 further comprising:
one or more heat exchange units for receiving heated coolant from the heat transfer units, dissipating heat from the coolant thereby creating cooled coolant, and directing the cooled coolant to the heat transfer units; and
transport means for transporting the coolant between the heat exchange units and the heat transfer units.

12. The cooling system as set forth in claim 11 wherein the transport means comprises:
one or more thin-walled, flexible conduits for transporting the coolant; and
support means disposed within the conduits for maintaining a consistent shape of the conduits in the electronic system.

13. A cooling system having a coolant for cooling one or more heat-generating components in an electronic system and having a coolant transport system, the coolant transport system comprising:
one or more thin-walled, flexible conduits for transporting the coolant; and
support means disposed within the conduits for maintaining a consistent shape of the conduits in the electronic system.

14. The cooling system as set forth in claim 13 for preventing undesired suction effects in the conduits.

15. The cooling system as set forth in claim 13 wherein the support means is a coil of suitably rigid material.

16. A server having the cooling system of claim 2.

17. A device having one or more heat-generating components and having the cooling system of claim 2.

18. A method of cooling one or more heat-generating components in an electronic system, the method comprising the step of:
thermally coupling one or more heat transfer units, secured directly or indirectly to the electronic system housing, with the one or more heat-generating units when the heat-generating components are connected to the electronic system, the heat transfer units having coolant circulating there through for transferring heat from the heat-generating components to the coolant.

19. The method of cooling as set forth in claim 18 wherein one or more heat-generating components are disposed on a circuit board, the method comprising the step of:
moving the heat transfer units into thermal coupling with the heat-generating components by connecting the circuit board to the electronic system.

20. The method of cooling as set forth in claim 19 wherein the heat transfer units are directly or indirectly pivoted or hinged to the housing of the electronic system.
